(19) United States
(12) Patent Application Publication
(10) Pub. No.: US 2026/0068106 A1
(43) Pub. Date: Mar. 5, 2026

(54) CONTAINER STRUCTURE AND SERVER CLUSTER

(71) Applicant: BITMAIN TECHNOLOGIES INC., Beijing (CN)

(72) Inventors: Hangkong HU, Beijing (CN); Hongshan ZHU, Beijing (CN); Shaoming HUANG, Beijing (CN); Zeqin SUN, Beijing (CN); Jian YAO, Beijing (CN); Tianhao LI, Beijing (CN); Jinkui WEI, Beijing (CN); Abdellah ESSAGHOURI, Beijing (CN)

(21) Appl. No.: 19/316,739

(22) Filed: Sep. 2, 2025

(30) Foreign Application Priority Data
Sep. 2, 2024 (CN) 202422153288.8

(51) Int. Cl. H05K 7/20

(52) U.S. Cl. CPC H05K 7/20836; H05K 7/20345; H05K 7/20736

(57) ABSTRACT

The present disclosure relates to a container structure and a server cluster, where the container structure includes: a box, in which a cold air channel and a hot air channel that are in communication with each other are formed; and a heat exchanger, disposed on the box and configured to exchange heat with air output from the hot air channel; where the heat exchanger has a heat exchange channel and an air channel, which are spaced apart; the heat exchange channel is respectively communicated with the cold air channel and the hot air channel, and can transmit air after heat exchange to the cold air channel; and an air exit and an air entrance of the air channel are disposed on adjacent sides of the heat exchanger.

### CROSS-REFERENCE TO RELATED APPLICATIONS

This application claims priority to Chinese Patent Application No. 202422153288.8, filed on Sep. 2, 2024, which is hereby incorporated herein by reference in its entirety.

### TECHNICAL FIELD

The present disclosure relates to the field of heat dissipation of computing devices, in particular, to a container structure and a server cluster.

### BACKGROUND

At present, a heat dissipation manner of a container structure is an open heat dissipation manner. The open heat dissipation manner usually involves outside air being drawn into the interior of the container structure from one side of the container structure by the heat dissipation fan of the computing device, passing through the computing device inside the container structure, and then being output from another side of the container structure. Due to the fact that the outside air directly enters the interior of the container structure, the computing device inside the container structure is easily affected by the outside air, resulting in the computing device failing to operate normally.

### SUMMARY

To overcome the problems in related technologies, the present disclosure provides a container structure and a server cluster, which can reduce the impact of the outside air on the computing device accommodated in the container structure.

According to a first aspect of embodiments of the present disclosure, there is provided a container structure, including:
a box, in which a cold air channel and a hot air channel that are in communication with each other are formed; and
a heat exchanger, disposed on and configured to exchange heat with air output from the hot air channel;
where the heat exchanger has a heat exchange channel and an air channel, which are spaced apart;
the heat exchange channel is respectively communicated with the cold air channel and the hot air channel, and configured to transmit air after heat exchange to the cold air channel; and
an air exit and an air entrance of the air channel are disposed on adjacent sides of the heat exchanger.

In some embodiments, the air entrance of the air channel is disposed on a first side and/or a second side of the heat exchanger, and the first side and the second side are two opposite sides of the heat exchanger;
the air exit of the air channel is disposed on a third side of the heat exchanger adjacent to the first side and the second side, where the third side is disposed opposite to a side of the heat exchanger near the box.

In some embodiments, the cold air channel, the hot air channel, and the heat exchange channel are communicated to form an annular sealed channel.

In some embodiments, the container structure further includes:
a cooling apparatus, disposed near the air channel and configured to cool air transmitted through the air channel.

In some embodiments, the cooling apparatus includes a water curtain; and
the water curtain covers the air entrance of the air channel in the heat exchanger and is configured to reduce a temperature of air entering the air channel.

In some embodiments, the cooling apparatus includes a spray apparatus; and
the spray apparatus is located inside the heat exchanger and has a spray nozzle, the spray nozzle faces the air channel.

In some embodiments, a heat exchange fan is provided at the air exit of the air channel in the heat exchanger; and
the heat exchange fan is configured to accelerate a circulation velocity of air in the air channel of the heat exchanger.

In some embodiments, the container structure further includes:

a heater, disposed at an entrance of the cold air channel in the box and configured to heat air flowing into the cold air channel.

In some embodiments, the heat exchange channel has at least three channel segments, and adjacent two channel segments are intercommunicated and form an included angle.

In some embodiments, the box is formed with an air inlet and an air outlet;
the air inlet is respectively communicated with the cold air channel and the heat exchange channel; and
the air outlet is respectively communicated with the hot air channel and the heat exchange channel;
where the air inlet is a heat exchange outlet of the heat exchanger, and the air outlet is a heat exchange inlet of the heat exchanger; or, the air inlet is disposed opposite to and in communication with the heat exchange outlet of the heat exchanger, and the air outlet is disposed opposite to and in communication with the heat exchange inlet of the heat exchanger.

According to a second aspect of an embodiment of the present disclosure, there is provided a server cluster, including:
the container structure as described in the first aspect above; and
a computing device, set inside the box of the container structure and between the cold air channel and the hot air channel of the box.

In some embodiments, the computing device is provided with a built-in heat dissipation fan;
the heat dissipation fan is configured to transmit air from the cold air channel to the hot air channel, and to transmit air from the hot air channel to the heat exchange channel of the container structure; or, the heat dissipation fan is configured to transmit air from the cold air channel to the hot air channel;
the container structure further includes:
a circulating fan, disposed at an outlet of the hot air channel and configured to transmit air from the hot air channel to the heat exchange channel.

The technical solutions provided in the embodiments of the present disclosure may have the following beneficial effects:

Embodiments of the present disclosure not only achieve heat exchange of the air inside the box by a heat exchanger, but also form circulation of the air inside the box by the communication of the heat exchange channel with the cold air channel and the hot air channel, respectively. That is, the embodiments of the present disclosure are to achieve heat dissipation by the heat exchanger and the circulation of air inside the box, rather than by using outside air to enter the box. In this way, on one hand, the air inside the box can be more stable, reducing the impact of outside air on the computing device accommodated in the container structure, and thus achieving heat dissipation while maintaining the stable operation of the computing device; on the other hand, by circulating and heat-exchanging the air inside the box through the heat exchanger, the air inside the box can circulate better, thereby improving the heat dissipation effect of the computing device accommodated in the box.

It should be understood that the above general description and the subsequent detailed description are only exemplary and explanatory, and do not limit the present disclosure.

### BRIEF DESCRIPTION OF DRAWINGS

The accompanying drawings, which are incorporated into the specification and form a part of the specification, illustrate embodiments in accordance with the present disclosure and are used together with the specification to explain the principles of the present disclosure.

FIG. 1 is a schematic structural diagram of an existing container according to an exemplary embodiment.

FIG. 2 is a first schematic diagram of a container structure of the present disclosure according to an exemplary embodiment.

FIG. 3 is a second schematic diagram of a container structure of the present disclosure according to an exemplary embodiment.

FIG. 4 is a schematic diagram of position of a water curtain in a container structure of the present disclosure according to an exemplary embodiment.

FIG. 5 is a schematic diagram of position of a spray apparatus in a container structure of the present disclosure according to an exemplary embodiment.

FIG. 6 is a schematic structural diagram of a server cluster of the present disclosure according to an exemplary embodiment.

### DESCRIPTION OF REFERENCE NUMBERS

11. container; 20. container structure; 21. box; 22. heat exchanger; 30. computing device;
201. cold air channel; 202. hot air channel; 203. heat exchange channel; 204. air channel; 205. cooling apparatus; 205A. water curtain; 205B. spray apparatus; 206. heat exchange fan; 207. heater; 208. circulating fan.

### DESCRIPTION OF EMBODIMENTS

Exemplary embodiments will be described in detail herein, with examples shown in the accompanying drawings. When the following description involves accompanying drawings, unless otherwise indicated, the same numbers in different accompanying drawings represent the same or similar elements. Implementations described in the following exemplary embodiments do not represent all embodiments consistent with the present disclosure. On the contrary, they are only examples of apparatuses consistent with some aspects of the present disclosure as detailed in the accompanying claims.

In related technologies, FIG. 1 is a schematic structural diagram of an existing container according to an exemplary embodiment. As indicated by the arrow in FIG. 1, air enters directly from one side of the container 11 and exits from another side of the container 11. The temperature and humidity of the air, dust in the air, and corrosive gases carried by the air can all affect the computing device inside the container 11, accelerate the failure and damage of the computing device, and ultimately make the computing device unable to operate normally.

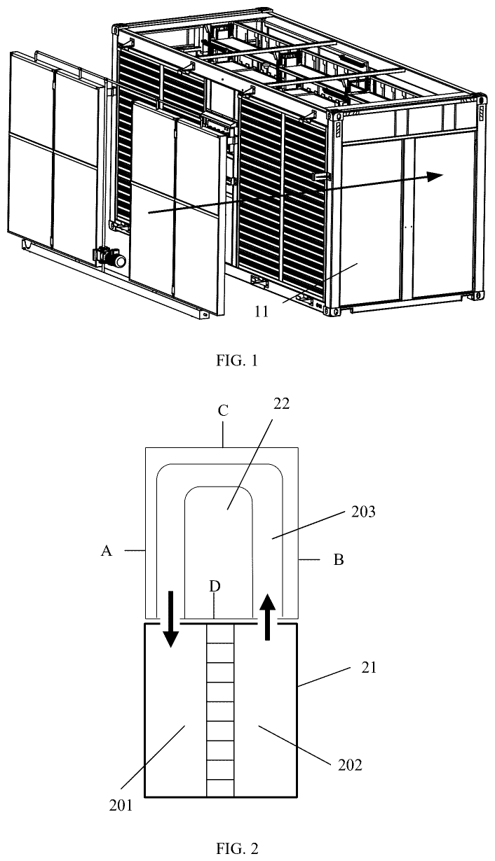

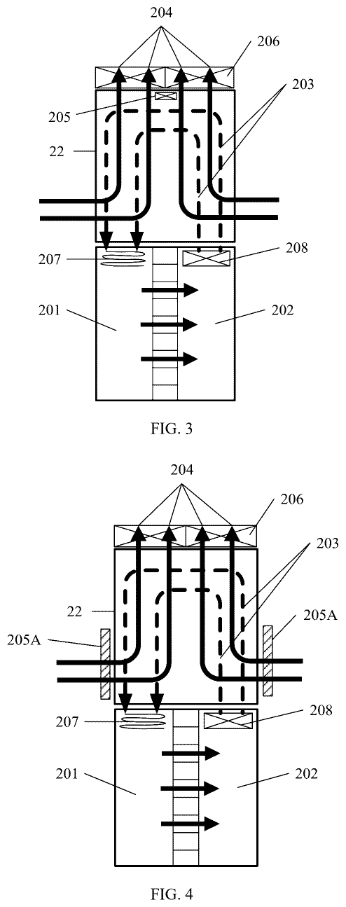

Based on this, an embodiment of the present disclosure provides a container structure, which can achieve the heat exchange of the air inside the box through the communication of the heat exchange channel with the cold air channel and the hot air channel, respectively, instead of directly using the outside air entering the container structure for heat dissipation. As shown in FIGS. 2 and 3, the container structure 20 includes:
a box 21, in which a cold air channel 201 and a hot air channel 202 that are in communication with each other are formed;
a heat exchanger 22, disposed on the box 21 and configured to exchange heat with air output from the hot air channel 202;
where the heat exchanger 22 has a heat exchange channel 203 and an air channel 204 that are spaced apart;
the heat exchange channel 203 is respectively communicated with the cold air channel 201 and the hot air channel 202, and is configured to transmit air after heat exchange to the cold air channel 201; and an air exit and an air entrance of the air channel 204 are disposed on adjacent sides of the heat exchanger 22.

In an embodiment of the present disclosure, the container structure 20 can be a structure for accommodating a computing device 30, and can be assembled from panels. In some embodiments, the container structure 20 may include a container, and the computing device 30 may be installed inside the box of the container, for ease of handling and installation.

It should be noted that the computing device 30 can perform centralized data management for efficient computation, as well as data storage. For example, the computing device 30 may include a mining device, and the embodiments of the present disclosure do not limit it.

In an embodiment of the present disclosure, the interior of the box 21 has an accommodating space, which can be formed with the cold air channel 201 and the hot air channel 202 in addition to accommodating the computing device 30.

It should be noted that the shape and size of the box 21 can be set according to actual needs, and the embodiments of the present disclosure do not limit it. For example, the box 21 can be set as a cuboid or a cube. For another example, the size of box 21 can be set based on the size and layout of the computing device 30 inside the box 21.

In an embodiment of the present disclosure, the cold air channel 201 and the hot air channel 202 may be two isolated channels.

In some embodiments, the computing device 30 may be disposed within the box 21 and form the cold air channel 201 and the hot air channel 202 on opposite sides of the computing device 30. The air inside the box 21 is transmitted from the cold air channel 201 to the hot air channel 202 after passing through the computing device 30.

This can achieve heat dissipation of the computing device 30.

In an embodiment of the present disclosure, in order to achieve better heat dissipation, the built-in heat dissipation fan of the computing device 30 can be used to achieve the air flowing from the cold air channel 201 into the hot air channel 202 to remove the heat from the computing device 30. An additional fan can also be provided within the container structure 20 to achieve the air flowing from the cold air channel 201 into the hot air channel 202.

In an embodiment of the present disclosure, the heat exchanger 22 is used to exchange heat with the air output from the hot air channel 202, that is, it enables the heat in the air output from the hot air channel 202 to be transferred to the air inside the air channel 204 in the heat exchanger 22, so as to achieve the purpose of heat exchange.

The heat exchange channel 203 of the above-mentioned heat exchanger 22 is respectively communicated with the cold air channel 201 and the hot air channel 202, so that the heat exchanger 22 can not only obtain the air output from the hot air channel 202 to conduct heat exchange, but also transmit the air after heat exchange to the cold air channel 201. In this way, the heat exchanger 22 can not only achieve heat exchange of the air inside the box 21, but also form a circulation of air inside the box 21, thereby achieving effective heat dissipation for the computing device 30 installed inside the box 21.

It should be noted that, as shown in FIG. 2, the arrow at the communication between the cold air channel 201 and the heat exchange channel 203 indicates that the heat exchange channel 203 will output the air after heat exchange to the cold air channel 201; the arrow at the communication between the hot air channel 202 and the heat exchange channel 203 indicates that the hot air channel 202 will output air to the heat exchange channel 203.

That is to say, the air entering the cold air channel 201 is the air output from the heat exchange channel 203 after heat exchange, and will be transmitted to the hot air channel 202, and then is output from the hot air channel 202 to the heat exchange channel 203 of the heat exchanger 22. This process is repeated to form circulation of the air inside the box 21 to achieve heat dissipation. Due to the fact that the circulation of the air inside the box 21 does not utilize the effect of outside air, the heat dissipation achieved by the embodiments of the present disclosure is not affected by the outside air, which can reduce the internal corrosion, condensation short circuit, and low-temperature startup failure of the computing device caused by moisture, dust, cold air, and corrosive gases in the outside air. Therefore, the embodiments of the present disclosure can achieve heat dissipation on the basis of maintaining the stable operation of the computing device 30.

Exemplarily, the heat exchanger 22 can also be referred to as a thermal exchanger. The thermal exchanger may include a dividing-wall heat exchanger, a mixing heat exchanger, a heat accumulating heat exchanger, a double-pipe heat exchanger, etc., and the embodiments of the present disclosure do not limit it.

In an embodiment of the present disclosure, the air channel 204 has an air entrance and an air exit. The number of the air entrance and the air exit can be set according to actual needs, and the embodiments of the present disclosure do not limit it.

In some embodiments, there is one air entrance. The air entrance and the air exit can be respectively disposed on two opposite sides of the heat exchanger 22 or on two adjacent sides of the heat exchanger 22.

Of course, the air entrance can also be provided in plurality, which are respectively disposed on different sides of the heat exchanger 22 or spaced apart on the same side thereof, and the embodiments of the present disclosure do not limit it. It can be understood that by disposing the air exit and the air entrance of the air channel 204 on adjacent sides of the heat exchanger 22, more heat exchange can be achieved, thereby improving the heat exchange effect of the heat exchanger.

In the embodiments of the present disclosure, the cold air channel 201 and the hot air channel 202 are formed inside the box 21 of the container structure 20, the heat exchange channel 203 of the heat exchanger 22 is respectively communicated with the cold air channel 201 and the hot air channel 202, and can perform heat exchange on the hot air channel 202 when the air in the cold air channel 201 passes through the hot air channel 202, and transmit the air after heat exchange to the cold air channel 201. That is to say, not only can heat exchange of the air inside the box 21 be achieved through the heat exchanger 22, but also circulation of the air inside the box 21 is formed through the communication of the heat exchange channel 203 with the cold air channel 201 and the hot air channel 202, respectively. That is, the embodiments of the present disclosure achieve heat dissipation through the heat exchanger 22 and the circulation of air inside the box 21, rather than through outside air entering the box.

In this way, on one hand, the air inside the box is enabled to be more stable, reducing the impact of outside air on the computing device accommodated in the container structure, and thus achieving heat dissipation on the basis of maintaining the stable operation of the computing device; on the other hand, by circulating and exchanging heat with the air inside the box through the heat exchanger, the air inside the box can circulate better, thereby improving the heat dissipation effect of the computing device accommodated in the box.

In some embodiments, as shown in FIGS. 2 and 3, the air entrance of the air channel 204 is disposed on a first side A and/or a second side B of the heat exchanger 22, and the first side A and the second side B are two opposite sides of the heat exchanger 22; and the air exit of the air channel 204 is disposed on a third side C of the heat exchanger 22 adjacent to the first side A and the second side B; where the third side Cis disposed opposite to a side of the heat exchanger 22 near the box 21.

In an embodiment of the present disclosure, the side of the heat exchanger 22 near the box 21 can be a fourth side D. A heat exchange inlet and a heat exchange outlet of the heat exchange channel 203 can be spaced apart on the fourth side D.

The third side C of the heat exchanger 22 can be the side where the top of the heat exchanger 22 is located, the fourth side D of the heat exchanger 22 can be the side where the bottom of the heat exchanger 22 is located, and the first side A and the second side B of the heat exchanger 22 can be the sides connecting the top with the bottom.

In an embodiment of the present disclosure, by providing the air entrances on the first side A and the second side B, more outside air can participate in heat exchange, thereby improving the heat exchange effect of the heat exchanger.

It should be noted that a plurality of air channels 204 can share one air exit, where one air channel can be disposed as corresponding to the one air exit, and the embodiments of the present disclosure do not limit it.

In some embodiments, as shown in FIG. 2, the cold air channel 201, the hot air channel 202, and the heat exchange channel 203 are intercommunicated to form an annular sealed channel.

Two ends of the heat exchange channel 203 are formed with a first channel port and a second channel port. The first channel port of the heat exchange channel 203 is communicated with the cold air channel 201, and the second channel port of the heat exchange channel 203 is communicated with the hot air channel 202. The cold air channel 201 and the hot air channel 202 are intercommunicated, and thus the cold air channel 201, the hot air channel 202, and the heat exchange channel 203 are intercommunicated and can form an annular sealed channel.

It should be noted that, in an embodiment of the present disclosure, a position where the cold air channel 201 is communicated with the heat exchange channel 203, and a position where the hot air channel 202 is communicated with the heat exchange channel 203 are each provided with a sealing component, to improve the sealing effect. Where the sealing component can be provided according to actual needs, as long as it can achieve a sealing effect, and the embodiments of the present disclosure do not limit it.

In an embodiment of the present disclosure, the air inside the box 21 will circulate in the annular sealed channel formed between the cold air channel 201, the hot air channel 202, and the heat exchange channel 203, that is, the embodiment of the present disclosure adopts a closed internal circulation manner to achieve the circulation of air inside the box.

It can be understood that by forming the annular sealed channel, it is possible to better reduce the internal corrosion, condensation short circuit, and low-temperature startup failure of the computing device caused by moisture, dust, cold air, and corrosive gas in the outside air, thereby achieving better heat dissipation while maintaining the stable operation of the computing device.

In an embodiment of the present disclosure, as shown in FIG. 3, there may be a plurality of heat exchange channels 203 formed in the heat exchanger 22, and each heat exchange channel 203 in the plurality of heat exchange channels 203 is communicated with the cold air channel 201 and the hot air channel 202. The heat exchanger 22 has an air channel 204, and the positive projection of the air channel 204 onto the heat exchange channel 203 at least partially overlaps with the heat exchange channel 203.

It should be noted that the plurality of heat exchange channels 203 can be stacked and spaced within the shell of the heat exchanger 22. Here, the heat exchange effect can be improved by providing a plurality of heat exchange channels 203.

In some embodiments, the heat exchange channel 203 has at least three channel segments, adjacent two channel segments are intercommunicated and form an included angle.

The positive projection of the above different channel segments onto the air channel 204 in the heat exchanger 22 can at least partially overlap with the air channel 204.

In an embodiment of the present disclosure, by providing a plurality of channel segments, it is possible to increase the heat exchange between the air in the heat exchange channel and the air in the air channel of the heat exchanger, thereby improving the heat exchange effect.

Exemplarily, as shown in FIG. 2, the heat exchange channel 203 is formed by communicating three channel segments in sequence, and the heat exchange channel 203 can be inverted U-shaped.

In some embodiments, as shown in FIG. 3, the container structure further includes:
a cooling apparatus 205, disposed near the air channel 204 and configured to cool air transmitted through the air channel 204.

In an embodiment of the present disclosure, the heat of the air in the heat exchange channel 203 can be transferred to the air in the air channel 204, that is, the air in the air channel 204 absorbs heat while being heated, and the air in the heat exchange channel 203 is cooled while releasing heat, thereby achieving heat exchange between the two channels. Here, the air transmitted in the air channel 204 is outside air.

It should be noted that the heat exchanger 22 can have a plurality of stacked air channels 204 and a plurality of stacked heat exchange channels 203, and one heat exchange channel 203 can be stacked between adjacent two air channels 204. In this way, the air inside the air channel 204 can better act on the heat exchange channel 203 to achieve better heat exchange effect.

Here, the air channel 204 and the heat exchange channel 203 that are adjacent to each other are isolated from each other. In an embodiment of the present disclosure, a thermal conductive polymer material can be provided between the air channel 204 and the heat exchange channel 203 that are adjacent to each other, to improve the heat exchange effect.

In an embodiment of the present disclosure, the cooling apparatus 205 being disposed near the air channel 204 may include that: the cooling apparatus 205 is disposed outside the heat exchanger 22 and attached to the inlet of the air channel 204, or it may be disposed inside the heat exchanger 22 and close to the air channel 204, and the embodiments of the present disclosure do not limit it.

It can be understood that the cooling apparatus can be used to cool the air transmitted through the air channel, in order to improve the heat exchange effect of the heat exchanger.

In some embodiments, as shown in FIGS. 3 and 4, the cooling apparatus 205 includes a water curtain 205A; and
the water curtain 205A covers the air entrance of the air channel 204 in the heat exchanger 22 and is configured to reduce a temperature of air entering the air channel 204.

In an embodiment of the present disclosure, the water curtain 205A is disposed outside the heat exchanger 22 and can be attached to the side wall where the air entrance of the heat exchanger 22 is located. Here, the size of the water curtain 205A can be set according to the size of the air entrance of the air channel 204, and the embodiments of the present disclosure do not limit it.

For example, the size of the water curtain 205A can be set to be greater than or equal to the size of the air entrance, so that the water curtain 205A can block the air entrance.

It should be noted that if the air entrance is disposed on the first and second sides of the heat exchanger 22, then the water curtain 205A is disposed on the side walls of the first and second sides of the heat exchanger 22. In this way, by cooling the air at the air entrance disposed on the first and second sides, the temperature of the air entering the air channel can be better reduced, improving the heat exchange effect of the heat exchanger.

In an embodiment of the present disclosure, by providing the water curtain 205A to cover the air entrance of the heat exchanger 22, the temperature of the air entering the air channel 204 can be reduced, thereby improving the heat exchange effect of the heat exchanger 22.

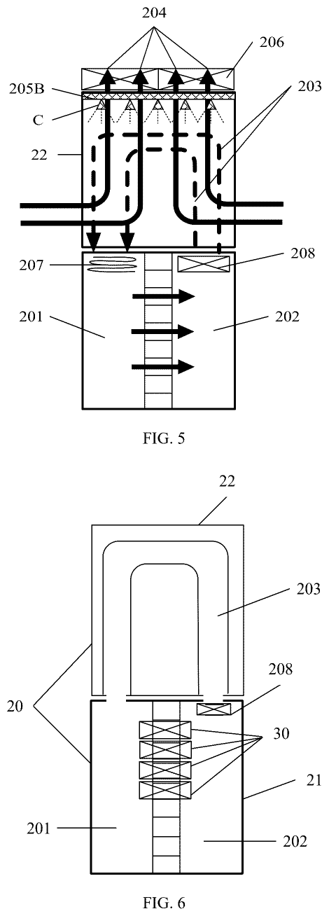

In some embodiments, as shown in FIGS. 3 and 5, the cooling apparatus 205 includes a spray apparatus 205B; and
the spray apparatus 205B is located inside the heat exchanger 22 and has a spray nozzle C, and the spray nozzle C faces the air channel 204.

In an embodiment of the present disclosure, the spray apparatus 205B is configured to reduce the temperature of the air transmitted in the air channel 204. Here, the spray apparatus 205B can spray a liquid from the spray nozzle to the air channel 204 so as to reduce the temperature of the air transmitted inside the air channel 204.

It should be noted that the liquid sprayed from the spray nozzle may include water or other solution, and the embodiments of the present disclosure do not limit it.

In an embodiment of the present disclosure, the number of the spray nozzle provided in the heat exchanger 22 can be consistent with the number of the air channel 204, so that one spray nozzle can face one air channel 204 and spray the liquid onto the air channel 204 to reduce the temperature of the air in the corresponding air channel 204.

Of course, the heat exchanger 22 can also be configured with more spray nozzles than the air channel 204. As such, a plurality of spray nozzles face the same air channel 204 to better reduce the temperature of the air inside the same air channel 204.

Of course, the heat exchanger 22 can also be configured with fewer spray nozzle than the air channels 204. As such, one spray nozzle can face a plurality of air channels 204 and spray the liquid onto the plurality of air channels 204.

Exemplarily, the spray apparatus 205B may include at least a pipeline, a water tank, and a pump in addition to the spray nozzle, to enable the pump to output the liquid in the water tank through the pipeline to the spray nozzle, so that the spray nozzle can spray the liquid.

In an embodiment of the present disclosure, a heat exchange fin of the heat exchanger 22 can enclose the air channel 204. The spray nozzle can be directed towards the air channel by spraying the liquid towards the heat exchange fin. Here, spraying the liquid onto the heat exchange fin can obtain a better heat exchange effect through evaporation.

It should be noted that the container structure can be provided with both the water curtain and the spray apparatus, or it can be provided with the water curtain without the spray apparatus, or it can be provided with the spray apparatus without the water curtain. The embodiments of the present disclosure have no limitation on this.

In an embodiment of the present disclosure, the container structure can be provided with the water curtain to improve the heat exchange effect of the heat exchanger, and also be provided with the spray apparatus to improve the heat exchange effect of the heat exchanger. This may provide a more flexible way to improve the heat exchange capacity of the heat exchanger.

In some embodiment, as shown in FIGS. 3-5, a heat exchange fan 206 is provided at the air exit of the air channel 204 in the heat exchanger 22; and the heat exchange fan 206 is configured to accelerate a circulation velocity of air in the air channel 204 of the heat exchanger 22.

An air inlet of the above heat exchange fan 206 faces the air exit, and an air outlet of the heat exchange fan 206 faces away from the air exit. The heat exchange fan 206 is used to transmit the air in the air channel 204 of the heat exchanger 22 to outside of the heat exchanger 22, thereby accelerating the circulation velocity of the air in the air channel 204 of the heat exchanger 22.

It should be noted that if the air exit of the air channel 204 is provided at the top of the heat exchanger 22, the heat exchange fan 206 is also provided at the top of the heat exchanger 22, and the air inlet of the heat exchange fan 206 is communicated with the air exit.

In an embodiment of the present disclosure, providing the heat exchange fan at the air exit of the heat exchanger can accelerate the circulation velocity of the air in the air channel of the heat exchanger through the heat exchange fan, thereby further improving the heat exchange effect of the heat exchanger.

In some embodiments, as shown in FIGS. 3-5, the container structure further includes:

a heater 207, disposed at an entrance of the cold air channel 201 and configured to heat air flowing into the cold air channel 201.

The above heater 207 may include an electric heating wire, and the air flowing into the cold air channel 201 inside the box 21 can be heated through the electric heating wire.

In an embodiment of the present disclosure, by providing the heater 207 at the entrance of the cold air channel 201 in the box 21, it is possible to heat the air flowing into the cold air channel 201. Then, the heated air can circulate to different positions inside the box through the annular closed channel. In this way, the computing device inside the box can be safely started and operated in a cold environment.

In some embodiments, the box 21 is formed with an air inlet and an air outlet;
the air inlet is respectively communicated with the cold air channel and the heat exchange channel; and
the air outlet is respectively communicated with the hot air channel and the heat exchange channel;
where the air inlet is a heat exchange outlet of the heat exchanger, and the air outlet is a heat exchange inlet of the heat exchanger;
or,
the air inlet is disposed opposite to and in communication with the heat exchange outlet of the heat exchanger, and the air outlet is disposed opposite to and in communication with the heat exchange inlet of the heat exchanger.

In an embodiment of the present disclosure, if the air inlet is the heat exchange outlet of the heat exchanger 22 and the air outlet is the heat exchange inlet of the heat exchanger 22, that is to say, the heat exchanger 22 and the box 21 can share the air inlet and air outlet to output the air from the heating air channel 202 to the heat exchange channel 203, and to output the air in the heat exchange channel 203 after heat exchange to the cold air channel 201, then the number of the air inlet and the air outlet can be reduced, not only making the container structure simpler, but also reducing costs.

The above air inlet is disposed opposite to and in communication with the heat exchange outlet. Here the size and shape of the air inlet can be set according to the size and shape of the heat exchange outlet, so as to better communicate the air inlet with the heat exchange outlet. For example, the size of the air inlet can be set to be equal to the size of the heat exchange outlet, and the shape of the air inlet can be similar or equal to the shape of the heat exchange outlet.

Of course, the size and shape of the air outlet can be set according to the size and shape of the heat exchange inlet, in order to better communicate the air outlet and the heat exchange inlet. For example, the size of the air outlet can be set to be equal to the size of the heat exchange inlet, and the shape of the air outlet can be similar or equal to the shape of the heat exchange inlet.

In an embodiment of the present disclosure, the air inlet is disposed opposite to and in communication with a heat exchange outlet of the heat exchanger, and the air outlet is disposed opposite to and in communication with a heat exchange inlet of the heat exchanger. That is to say, the heat exchanger in the embodiment of the present disclosure can be assembled to the box, and after assembly, the air inlet and the heat exchange outlet of the heat exchanger are opposite and communicated, and the air outlet and the heat exchange inlet of the heat exchanger are opposite and communicated. This may facilitate the installation and handling of the container structure.

An embodiment of the present disclosure also proposes a server cluster. FIG. 6 is a schematic structural diagram of a server cluster shown in an embodiment of the present disclosure, and the server cluster includes:
the container structure as described in one or more embodiments above; and
a computing device 30, disposed inside the box 21 of the container structure 20 and between the cold air channel 201 and the hot air channel 202 of the box 21.

In an embodiment of the present disclosure, the space on both sides of the computing device 30 in the box 21 can respectively form the cold air channel 201 and the hot air channel 202. In this way, the air in the cold air channel 201 can pass through the computing device and be immediately transmitted to the hot air channel 202 to achieve heat dissipation for the computing device.

The above server cluster also includes an installation bracket, the installation bracket is provided inside the box of the container structure 20, and the computing device 30 is disposed on the installation bracket.

In an embodiment of the present disclosure, the server cluster includes one or more of the above container structures, and the embodiment of the present disclosure achieves heat dissipation through the heat exchanger in the container structure and the circulation of air inside the box, rather than through outside air entering the box. This, on one hand, can make the air inside the box more stable, reducing the impact of outside air on the computing device inside the container structure, and thus achieving heat dissipation on the basis of maintaining the stable operation of the computing device; on the other hand, circulating and heat-exchanging the air inside the box through the heat exchanger can make the air inside the box circulate better, thereby improving the heat dissipation effect of the computing device accommodated in the box.

In some embodiments, as shown in FIGS. 3-6, the computing device 30 is provided with a built-in heat dissipation fan (not shown); the heat dissipation fan is configured to transmit air from the cold air channel 201 to the hot air channel 202, and to transmit air from the hot air channel 202 to the heat exchange channel 203;
or,
the heat dissipation fan is configured to transmit air from the cold air channel 201 to the hot air channel 202;
the container structure further includes:
a circulating fan 208, disposed at an outlet of the hot air channel 202 and configured to transmit air from the hot air channel 202 to the heat exchange channel 203 of the container structure.

In this disclosed embodiment, use of the heat dissipation fan of the computing device 30 can transmit the air from the cold air channel 201 to the hot air channel 202, and transmit the air from the hot air channel 202 to the heat exchange channel 203. This enriches the functionality of the heat dissipation fan of the computing device, and improves the integration level of the device.

It should be noted that an exhaust outlet of the heat dissipation fan of the computing device 30 needs to face the hot air channel 202, so as to better transfer the air in the cold air channel to the hot air channel.

The above circulating fan and heat dissipation fan can be the same fan or different fans, and the embodiments of the present disclosure do not limit it.

In an embodiment of the present disclosure, two fans are used to respectively achieve air circulation to the hot air channel and to the heat exchange channel, which can better improve air circulation and thus enhance heat dissipation effect.

After considering the specification and practicing the invention disclosed herein, those skilled in the art will easily come up with other implementation solutions of the present disclosure. The present disclosure is intended to cover any variations, uses, or adaptive changes of the present disclosure that follow the general principles of the present disclosure and include common knowledge or customary technical means in the art that are not disclosed in the present disclosure. The specification and embodiments are only considered exemplary, and the true scope and spirit of the present disclosure are defined by the claims.

It should be understood that the present disclosure is not limited to the precise structure described above and shown in the accompanying drawings, and various modifications and changes can be made without departing from the scope of the present disclosure. The scope of the present disclosure is limited only by the appended claims.

What is claimed is:

1. A container structure, comprising:
a box, in which a cold air channel and a hot air channel that are in communication with each other are formed; and
a heat exchanger, disposed on and configured to exchange heat with air output from the hot air channel;
wherein the heat exchanger has a heat exchange channel and an air channel, which are spaced apart;
the heat exchange channel is respectively communicated with the cold air channel and the hot air channel, and configured to transmit air after heat exchange to the cold air channel;
an air exit and an air entrance of the air channel are disposed on adjacent sides of the heat exchanger.

2. The container structure according to claim 1, wherein the air entrance of the air channel is disposed on at least one of a first side or a second side of the heat exchanger, and the first side and the second side are two opposite sides of the heat exchanger; and
the air exit of the air channel is disposed on a third side of the heat exchanger adjacent to the first side and the second side, wherein the third side is disposed opposite to a side of the heat exchanger near the box.

3. The container structure according to claim 1, wherein the cold air channel, the hot air channel, and the heat exchange channel are intercommunicated to form an annular sealed channel.

4. The container structure according to claim 1, further comprising:
a cooling apparatus, disposed near the air channel and configured to cool air transmitted through the air channel.

5. The container structure according to claim 4, wherein the cooling apparatus comprises a water curtain; and
the water curtain covers the air entrance of the air channel and is configured to reduce a temperature of air entering the air channel.

6. The container structure according to claim 4, wherein the cooling apparatus comprises a spray apparatus; and
the spray apparatus is located inside the heat exchanger and has a spray nozzle, and the spray nozzle faces the air channel.

7. The container structure according to claim 1, wherein a heat exchange fan is provided at the air exit of the air channel in the heat exchanger; and
the heat exchange fan is configured to accelerate a circulation velocity of air in the air channel of the heat exchanger.

8. The container structure according to claim 1, further comprising:
a heater, disposed at an entrance of the cold air channel and configured to heat air flowing into the cold air channel.

9. The container structure according to claim 1, wherein the heat exchange channel has at least three channel segments, and adjacent two channel segments are intercommunicated and form an included angle.

10. The container structure according to claim 1, wherein the box is formed with an air inlet and an air outlet;
the air inlet is respectively communicated with the cold air channel and the heat exchange channel;
the air outlet is respectively communicated with the hot air channel and the heat exchange channel;
wherein the air inlet is a heat exchange outlet of the heat exchanger, and the air outlet is a heat exchange inlet of the heat exchanger; or, the air inlet is disposed opposite to and in communication with the heat exchange outlet of the heat exchanger, and the air outlet is disposed opposite to and in communication with the heat exchange inlet of the heat exchanger.

11. A server cluster, comprising:
a container structure, comprising: a box, in which a cold air channel and a hot air channel that are in communication with each other are formed; and a heat exchanger, disposed on and configured to exchange heat with air output from the hot air channel; wherein the heat exchanger has a heat exchange channel and an air channel, which are spaced apart; the heat exchange channel is respectively communicated with the cold air channel and the hot air channel, and configured to transmit air after heat exchange to the cold air channel; an air exit and an air entrance of the air channel are disposed on adjacent sides of the heat exchanger; and
a computing device, disposed inside the box of the container structure and between the cold air channel and the hot air channel of the box.

12. The server cluster according to claim 11, wherein the computing device is provided with a built-in heat dissipation fan;
the heat dissipation fan is configured to transmit air from the cold air channel to the hot air channel, and to transmit air from the hot air channel to a heat exchange channel of the container structure; or, the heat dissipation fan is configured to transmit air from the cold air channel to the hot air channel;
the container structure further comprises:
a circulating fan, disposed at an outlet of the hot air channel and configured to transmit air from the hot air channel to the heat exchange channel.

13. The server cluster according to claim 11, wherein the air entrance of the air channel is disposed on at least one of a first side or a second side of the heat exchanger, and the first side and the second side are two opposite sides of the heat exchanger; and
the air exit of the air channel is disposed on a third side of the heat exchanger adjacent to the first side and the second side, wherein the third side is disposed opposite to a side of the heat exchanger near the box.

14. The server cluster according to claim 11, wherein the cold air channel, the hot air channel, and the heat exchange channel are intercommunicated to form an annular sealed channel.

15. The server cluster according to claim 11, wherein the container structure further comprises:
a cooling apparatus, disposed near the air channel and configured to cool air transmitted through the air channel.

16. The server cluster according to claim 15, wherein the cooling apparatus comprises a water curtain; and
the water curtain covers the air entrance of the air channel and is configured to reduce a temperature of air entering the air channel.

17. The server cluster according to claim 15, wherein the cooling apparatus comprises a spray apparatus; and
the spray apparatus is located inside the heat exchanger and has a spray nozzle, and the spray nozzle faces the air channel.

18. The server cluster according to claim 11, wherein a heat exchange fan is provided at the air exit of the air channel in the heat exchanger, and the heat exchange fan is configured to accelerate a circulation velocity of air in the air channel of the heat exchanger.

19. The server cluster according to claim 11, wherein the container structure further comprises:
a heater, disposed at an entrance of the cold air channel and configured to heat air flowing into the cold air channel.

20. The server cluster according to claim 11, wherein the heat exchange channel has at least three channel segments, and adjacent two channel segments are intercommunicated and form an included angle.
